(19) United States
(12) Patent Application Publication
(10) Pub. No.: US 2013/0313717 A1
(43) Pub. Date: Nov. 28, 2013

(54) SPACER FOR ENHANCING VIA PATTERN OVERLAY TOLERENCE

(71) Applicants: Steven J. Holmes, Guilderland, NY (US); David V. Horak, Essex Junction, VT (US); Charles W. Koburger, III, Delmar, NY (US); Shom Ponoth, Clifton Park, NY (US); Chih-Chao Yang, Glenmont, NY (US)

(72) Inventors: Steven J. Holmes, Guilderland, NY (US); David V. Horak, Essex Junction, VT (US); Charles W. Koburger, III, Delmar, NY (US); Shom Ponoth, Clifton Park, NY (US); Chih-Chao Yang, Glenmont, NY (US)

(73) Assignee: INTERNATIONAL BUSINESS MACHINES CORPORATION, Armonk, NY (US)

(21) Appl. No.: 13/479,893

(22) Filed: May 24, 2012

(51) Int. Cl. H01L 23/48; H01L 21/768

(52) U.S. Cl. 257/774; 438/666; 257/E23.011; 257/E21.579

(57) ABSTRACT

After formation of line openings in a hard mask layer, hard mask level spacers are formed on sidewalls of the hard mask layer. A photoresist is applied and patterned to form a via pattern including a via opening. The overlay tolerance for printing the via pattern is increased by the lateral thickness of the hard mask level spacers. A portion of a dielectric material layer is patterned to form a via cavity pattern by an etch that employs the hard mask layer and the hard mask level spacers as etch masks. The hard mask level spacers are subsequently removed, and the pattern of the line is subsequently transferred into an upper portion of the dielectric material layer, while the via cavity pattern is transferred to a lower portion of the dielectric material layer.

### BACKGROUND

The present disclosure relates to a metal interconnect structure, and particularly to a metal interconnect structure that increases overlay tolerance for printing of a via pattern, and methods of manufacturing the same.

Lithographic capabilities are one of the significant technological limitations that constrain the continued scaling of semiconductor devices. Overlay variations are inherent in any alignment process that lithographically defines a new pattern in spatial registry with an existing pattern. Such overlay variations cause misalignment between existing patterns and a newly formed pattern.

As the minimum feature size continues to shrink with advancement of semiconductor technology, the overlay variations can cause formation of undesirable patterns by printing features in regions in which the features are not intended to be present. For example, a via pattern with a significant overlay error can overlie a line pattern that is not intended to overlap with the via pattern. In this case, a via structure can be formed under a line structure that is not designed to have any via structure underneath. In general, a via pattern needs to overlap only with a line pattern, and overlap of a via pattern with an adjacent line pattern should be avoided.

### BRIEF SUMMARY

After formation of line openings in a hard mask layer, hard mask level spacers are formed on sidewalls of the hard mask layer. The lateral thickness of the hard mask level spacers is less than one half of the minimum width of the line openings, and is selected to provide a separation distance that can be employed as a width of a via structure to be subsequently formed. A photoresist is applied over the patterned hard mask layer, and is lithographically patterned to form a via pattern including a via opening that overlies one of the line openings. The overlay tolerance for printing the via pattern is increased by the lateral thickness of the hard mask level spacers due to the presence of the hard mask level spacers. A pattern formed by an intersection of the via pattern and the openings within the hard mask level spacers is transferred into a portion of a dielectric material layer to form a via cavity pattern by an etch that employs the hard mask layer and the hard mask level spacers as etch masks. The hard mask level spacers are subsequently removed selective to the dielectric material layer. The pattern of the line openings in the hard mask layer is subsequently transferred into an upper portion of the dielectric material layer, while the via cavity pattern is transferred to a lower portion of the dielectric material layer.

According to an aspect of the present disclosure, a method of forming a metal interconnect structure is provided, which includes: forming a hard mask layer over a dielectric material layer; patterning the hard mask layer with a line pattern including a line opening having a first width; forming a hard mask level spacer on sidewalls of the line opening, wherein inner sidewalls of the hard mask level spacer define another line opening having a second width less than the first width; applying a photoresist layer over the hard mask layer and lithographically patterning the photoresist layer with a via pattern that includes a via opening overlying the another line opening; and transferring, employing an etch, a composite pattern including an intersection of the via opening and the another line opening into a portion of the dielectric material layer.

According to another aspect of the present disclosure, a metal interconnect structure is provided, which includes an integrated line and via structure of integral construction embedded in a dielectric material layer, the integrated line and via structure including a metal line having a first width and a via structure having two parallel sidewalls spaced by a second width that is less than the first width.

### BRIEF DESCRIPTION OF THE SEVERAL VIEWS OF THE DRAWINGS

FIG. 1 is a schematic vertical cross-sectional view of an exemplary structure after formation of a hard mask layer on a dielectric material layer according to an embodiment of the present disclosure.

FIG. 2 is a schematic vertical cross-sectional view of the exemplary structure after patterning of the hard mask layer according to an embodiment of the present disclosure.

FIG. 3 is a schematic vertical cross-sectional view of the exemplary structure after formation of hard mask level spacers according to an embodiment of the present disclosure.

FIG. 4 is a schematic vertical cross-sectional view of the exemplary structure after formation of a first via cavity according to an embodiment of the present disclosure.

FIG. 5 is a schematic vertical cross-sectional view of the exemplary structure after formation of a second via cavity according to an embodiment of the present disclosure.

FIG. 6 is a schematic vertical cross-sectional view of the exemplary structure after removal of a photoresist layer according to an embodiment of the present disclosure.

FIG. 7 is a schematic vertical cross-sectional view of the exemplary structure after removal of the hard mask level spacers according to an embodiment of the present disclosure.

FIG. 8 is a schematic vertical cross-sectional view of the exemplary structure after a dual damascene etch that forms line cavities and dual damascene cavities according to an embodiment of the present disclosure.

FIG. 9 is a schematic vertical cross-sectional view of the exemplary structure after formation of metallic lines and dual damascene line-via structures according to an embodiment of the present disclosure.

FIG. 10 is a schematic see-through top-down view of the exemplary structure of FIG. 9, which illustrates lateral boundaries of the metallic lines and the dual damascene line-via structures according to an embodiment of the present disclosure.

FIG. 11 is a schematic vertical cross-sectional view of a variation of the exemplary structure according to an embodiment of the present disclosure.

FIG. 12 is a schematic vertical cross-sectional view of the exemplary structure after formation of an overlying dielectric material layer and overlying metal interconnect structures according to an embodiment of the present disclosure.

### DETAILED DESCRIPTION

As stated above, the present disclosure relates to a metal interconnect structure that increases overlay tolerance for printing of a via pattern, and methods of manufacturing the same, which are now described in detail with accompanying figures. It is noted that like and corresponding elements are referred to by like reference numerals. The drawings are not in scale.

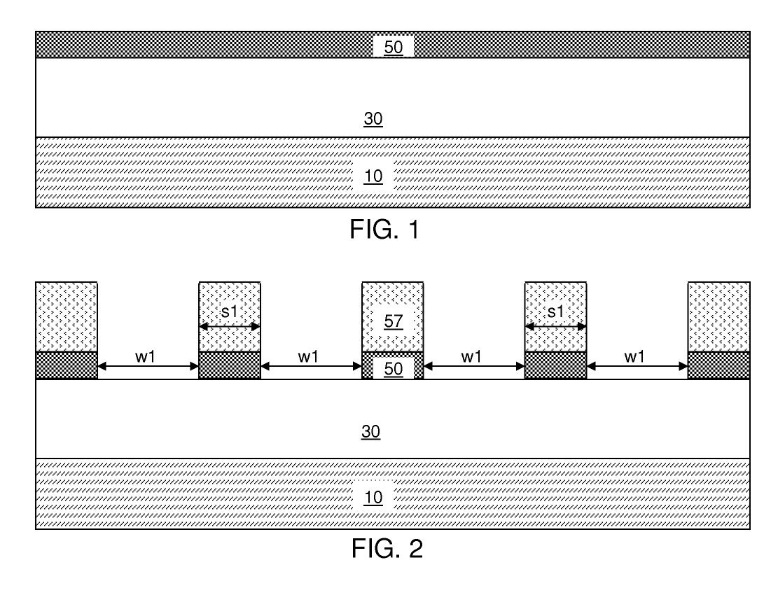

Referring to FIG. 1, an exemplary structure according to an embodiment of the present disclosure includes a substrate 10, a dielectric material layer 30 formed on the substrate 10, and a hard mask layer 50 formed on the dielectric material layer 30. The substrate 10 can include a semiconductor substrate on which at least one semiconductor device (not separately shown) is present. Optionally, the substrate 10 may further include at least one underlying dielectric material layer (not shown separately) and metal interconnect structures (not shown separately) embedded therein such as metal lines and/metal vias.

The semiconductor substrate includes a semiconductor material, which can be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The semiconductor substrate can be a bulk semiconductor substrate or a semiconductor-on-insulator (SOI) substrate. The at least one semiconductor device can be a field effect transistor, a bipolar transistor, a diode, a resistor, a capacitor, an inductor, an electrically programmable fuse, or any combination thereof.

The at least one underlying dielectric material layer and metal interconnect structures, if present, can be provided in an upper portion of the substrate 10. The at least one underlying dielectric material layer can include any dielectric material as known in the art for embedding metal interconnect structures. The metal interconnect structures embedded within the at least one underlying dielectric material layer can be any metal interconnect structure known in the art.

The dielectric material layer 30 includes a dielectric material, which can be a conventional dielectric material such as undoped silicon oxide (undoped silicate glass), doped silicon oxide (doped silicate glass), silicon oxynitride, silicon nitride, or a combination thereof, or can be a low dielectric constant (low-k) material, which refers to a dielectric material having a dielectric constant less than the dielectric constant of silicon oxide, i.e., 3.9. Low dielectric constant materials that can be employed for the dielectric material layer 30 include organosilicate glass including Si, C, O, H, and optionally N, and methylated-hydrogen silsesquioxane (MSQ). The low dielectric constant material can be deposited by chemical vapor deposition or by spin-coating, and can be porous or non-porous. The dielectric material layer 30 is formed at an interconnect level, i.e., at a level in which metal interconnect structures are present. The thickness of the dielectric material layer 30 can be from 30 nm to 600 nm, and typically from 60 nm to 300 nm, although lesser and greater thicknesses can also be employed.

The dielectric material layer 30 can have a homogeneous composition throughout, or can include a vertical stack of multiple dielectric material layers each having a homogeneous composition. In one embodiment, the dielectric material layer 30 can have a homogenous composition within a height range including a target depth for bottom surfaces of metal lines to be subsequently formed. In one embodiment, the dielectric material layer 30 can have a homogenous composition throughout the entirety thereof.

A hard mask layer 50 is deposited on a planar top surface of the dielectric material layer 30. The hard mask layer 50 can be a metal layer, an intermetallic alloy layer, a metallic nitride layer, a metallic carbide layer, a metal oxide layer, another dielectric material layer having a different composition than the dielectric material layer 30, or a combination or a stack thereof. Non-limiting examples of elemental metals that can be employed in a metal layer within the hard mask layer 50 include W, Ti, Ta, Al, Ni, Co, Au, and Ag. Thus, the hard mask layer 50 can be a single layer having a homogenous composition throughout, or can be a stack of multiple layers each having a homogeneous composition therein.

Non-limiting examples of elemental metals that can be employed in an intermetallic alloy layer within the hard mask layer 50 include W, Ti, Ta, Al, Ni, Co, Au, and Ag. Non-limiting examples of metallic nitrides that can be employed in a metallic nitride layer within the hard mask layer 50 include WN, TiN, TaN, and AN. Non-limiting examples of metallic carbides that can be employed in a metallic carbide layer within the hard mask layer 50 include WC, TiC, and TaC. Non-limiting examples of metal oxides that can be employed in a metal oxide layer within the hard mask layer 50 include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y2OₓN_{y}, a silicate thereof, and an alloy thereof. Each value of x is independently from 0.5 to 3 and each value of y is independently from 0 to 2. Non-limiting examples of a dielectric material having a different composition than the dielectric material layer 30 include silicon nitride if the dielectric material layer 30 does not include a silicon nitride material, and a nitrogen-containing organosilicate glass if the dielectric material layer 30 does not include a nitrogen-containing organosilicate glass.

The hard mask layer 30 can be deposited employing any deposition method known in the art for the material(s) selected for the hard mask layer 30. Deposition methods that can be employed to form the hard mask layer 30 include, but are not limited to, physical vapor deposition, vacuum evaporation, chemical vapor deposition (CVD), molecular beam deposition (MBD), pulsed laser deposition (PLD), liquid source misted chemical deposition (LSMCD), and atomic layer deposition (ALD). The thickness of the hard mask layer 30 can be from 1 nm to 30 nm, although lesser and greater thicknesses can also be employed.

Referring to FIG. 2, a photoresist layer 57 is applied over the top surface of the hard mask layer 50, and is subsequently patterned lithographically, i.e., by lithographic exposure to illumination that passes through a patterned lithographic mask and subsequent development of the photoresist layer 57. The pattern in the lithographically patterned photoresist layer 57 is subsequently transferred through the hard mask layer employing an etch, which can be, for example, an anisotropic etch that employs the photoresist layer 57 as a etch mask. Thus, the lithographic pattern in the photoresist layer 57 is duplicated in the hard mask layer 50.

In one embodiment, the etch employed to pattern the hard mask layer 50 can terminate after a predetermined overetch time upon detection of the physical exposure of a top surface of the dielectric material layer 30. The predetermined overetch time and/or the chemistry of the etch can be selected to minimize any indentation of the top surface of the dielectric material layer 30 after patterning of the hard mask layer 50.

In one embodiment, the pattern in the hard mask layer 50 can include at least one line pattern, i.e., a pattern of at least one line. One or more of the at least one line pattern can have an opening in the hard mask layer 50 having a uniform width, which is herein referred to as a first width w1. In other words, at least one opening in the hard mask layer 50 can be defined by a pair of parallel sidewalls of the hard mask layer 50 separated by the first width w1 that remains invariant under movement along a horizontal direction perpendicular to the direction of the first width w1. The horizontal direction that is perpendicular to the direction of the first width w1 is herein referred to as a lengthwise direction of the at least one opening.

In one embodiment, a plurality of openings having a first width w1 can be formed in the hard mask layer 50. In another embodiment, the openings within the plurality of openings having a first width w1 can be laterally spaced from an adjacent opening by a spacing, which is herein referred to as a first spacing s1. In this case, the plurality of openings can be formed with a periodicity along the direction of the first width w1 with a pitch that is the same as the sum of the first width w1 and the first spacing s1. The photoresist layer 57 is subsequently removed, for example, by ashing.

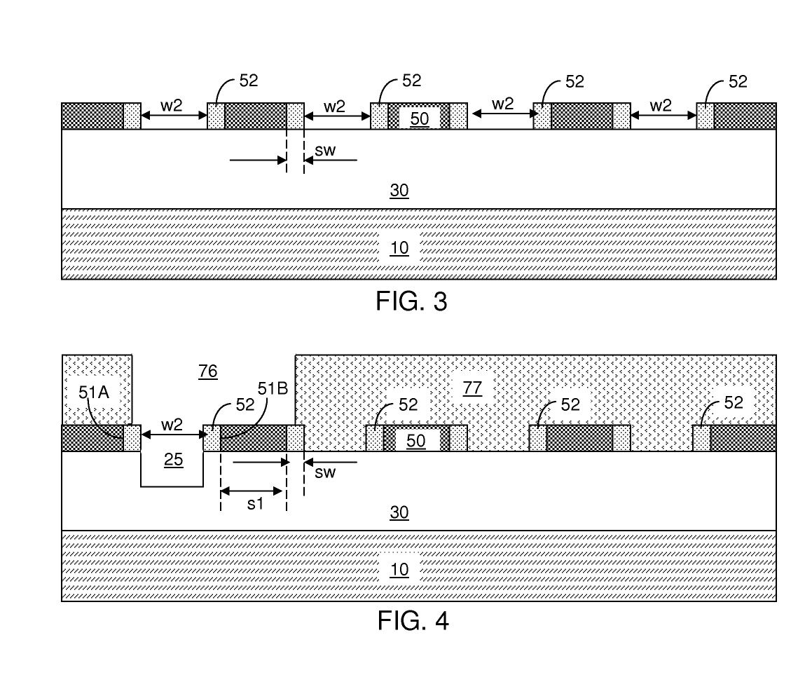

Referring to FIG. 3, hard mask level spacers 52 are formed on sidewalls of the hard mask layer 50. As used herein, a “hard mask level spacer” refers to a spacer that is located within a hard mask level, i.e., between a topmost surface and a bottommost surface of the hard mask layer.

The hard mask level spacers 52 can be formed by depositing a contiguous material layer over the hard mask layer 50 and within the line opening. In one embodiment, the contiguous material layer can be a conformal layer having a same thickness on horizontal surfaces and vertical surfaces. The thickness of the contiguous material layer is less than one half of the first thickness t1 so that the openings in the hard mask layer 50 are not plugged by the contiguous material layer.

The contiguous material layer has a composition different from the hard mask layer 50 and the dielectric material layer 30. In one embodiment, the material of the contiguous material layer can be selected from germanium, a silicon germanium alloy, an oxide of a silicon germanium alloy, parylene, amorphous carbon, and a hydrogen-containing silicon nitride material. The contiguous material layer can be deposited in any method known in the art for depositing the selected material for the contiguous material layer. Non-limiting examples of deposition methods that can be employed to deposit the contiguous material layer include, but are not limited to, chemical vapor deposition (CVD), physical vapor deposition (PVD), and atomic layer deposition (ALD). A hydrogen-containing silicon nitride material can be deposited, for example, by plasma enhanced chemical vapor deposition (PECVD) process that employs hydrogen gas during a deposition step.

The material of the contiguous material layer is selected such that the material of the contiguous material layer can be removed selective to the material of the hard mask layer 50 and the material of the dielectric material layer 30 in a subsequent processing step.

The contiguous material layer is anisotropically etched to remove horizontal portions of the contiguous material layer. The anisotropic etching of the contiguous material layer can be effected, for example, by a reactive ion etch. After removal of the horizontal portions of the contiguous material layer, the remaining portions of the contiguous material layer constitute the hard mask level spacers 52.

A hard mask level spacer 52 is formed on sidewalls of each opening within the hard mask layer 52, including sidewalls of each line opening having the first width w1. The lateral thickness of each hard mask level spacer 52 is herein referred to as a spacer width sw. Each contiguous set of outer sidewalls of a hard mask level spacer 52 contacts a contiguous set of sidewalls around an opening, which can be a line opening, of the hard mask layer 52 as formed at the processing step of FIG. 2. If the opening is a line opening at the processing step of FIG. 2, a contiguous set of inner sidewalls of the hard mask level spacer 52 defines another line opening having a second width w2, which is less than the first width w1 by twice the spacer width sw. In other words, w2=w1−2×sw.

In one embodiment, a hard mask level spacer 52 can laterally surround a line opening having the second width w2, and can include two parallel portions that are laterally separated by the second width w2.

Referring to FIG. 4, a first via level photoresist layer 77 is applied over the patterned hard mask layer 50, the dielectric material layer 30, and the hard mask level spacers 52, for example, by spin coating. The first via level photoresist layer 77 is lithographically patterned with a via pattern including a first via opening 76. The via pattern in the lithographically patterned first via level photoresist layer 77 is herein referred to as a first via pattern. The first via opening 76 overlies a line opening having the second width w2, and can overlie all or a portion of the hard mask level spacer 52 that laterally surrounds the line opening. Further, the first via opening 76 can overlie any portion of the hard mask layer 50 around the line opening and the hard mask level spacer 52. In addition, the first via opening 76 can overlie any other hard mask level spacer 52, provided that the first via opening 76 does not overlie another line opening at which formation of a via is not desired. The first via pattern can include any additional first via opening(s) (not expressly shown) as needed.

The presence of the hard mask level spacer 52 extends the overlay window for printing the first via opening 76 along the direction of the second width w2. For example, if the hard mask level spacers 52 are not present in the exemplary structure of FIG. 4, a right side sidewall of the first via opening 76 must fall on a portion of a top surface of the hard mask layer 50 between the leftmost opening in the hard mask layer 50 and the second opening from the left side in the hard mask layer 50. In this case, the overlay tolerance for printing of the first via pattern along the direction of the second width w2 is the same as the first spacing s1. The presence of the hard mask level spacers 52 in the exemplary structure of FIG. 4 increases the overlay tolerance for printing of the first via pattern along the direction of the second width w2 by the spacer width sw because the right side sidewall of the first via opening 76 can fall on the hard mask level spacer 52 around the second line opening from the left in the exemplary structure of FIG. 4. Further, if the hard mask level spacers 52 are not present in the exemplary structure of FIG. 4, a left side sidewall of the first via opening 76 must fall on the leftmost portion of the top surface of the hard mask layer 50. The presence of the hard mask level spacers 52 in the exemplary structure of FIG. 4 increases the overlay tolerance for printing of the first via pattern along the direction of the second width w2 by the spacer width sw because the left side sidewall of the first via opening 76 can fall on the hard mask level spacer 52 around the leftmost line opening in the exemplary structure of FIG. 4.

Subsequently, an etch is performed to form at least one via cavity in a portion of the dielectric material layer 30. The etch is herein referred to as a first via etch, and employs the first via level photoresist layer 77, the hard mask layer 50, and the hard mask level spacers 52 as etch masks. The first via etch can be an anisotropic etch such as a reactive ion etch. The at least one via cavity is formed within an area corresponding to a composite pattern of an intersection of the first via pattern and the openings defined by inner sidewalls of the hard mask level spacers 52. Because the first via pattern includes the first via opening 76, the at least one via cavity can include a first via cavity 25 that is formed in an area corresponding to an intersection of the first via opening 76 and a line opening defined by the inner sidewalls of a hard mask level spacer 52, i.e., the hard mask level spacer 52 in the leftmost opening in the hard mask layer 50 in FIG. 4.

The first via cavity 25 includes two parallel sidewalls that are laterally spaced by the second width w2. One of the two parallel sidewalls of the first via cavity 25 is laterally offset from a first sidewall 51A of the hard mask layer 50 (i.e., the left side sidewall around the leftmost opening in the hard mask layer 50) by an offset distance that is the same as the spacer width sw, and another of the two parallel sidewalls of the hard mask layer 50 is laterally offset from a second sidewall 51B of the hard mask layer 50 (i.e., the right side sidewall around the leftmost opening in the hard mask layer 50) by the same offset distance, i.e., the spacer width sw.

A pair of sidewalls (not shown) of the first via cavity 25 that laterally adjoins the two parallel sidewalls of the first via cavity 25 replicates two peripheral portions of a horizontal cross-sectional shape of the first via opening 76 that overlies the line opening (i.e., the leftmost line opening having the second width w2). In this case, the pair of sidewalls of the first via cavity 25 can be a pair of curvilinear sidewalls. As used herein, a curvilinear shape includes a curved shape that cannot be contained with a two-dimensional Euclidean plane and a liner shape that can be contained within a two-dimensional Euclidean plane. Thus, the pair of sidewalls of the first via cavity 25 can be straight or curved. The first via level photoresist layer 77 is removed, for example, by ashing.

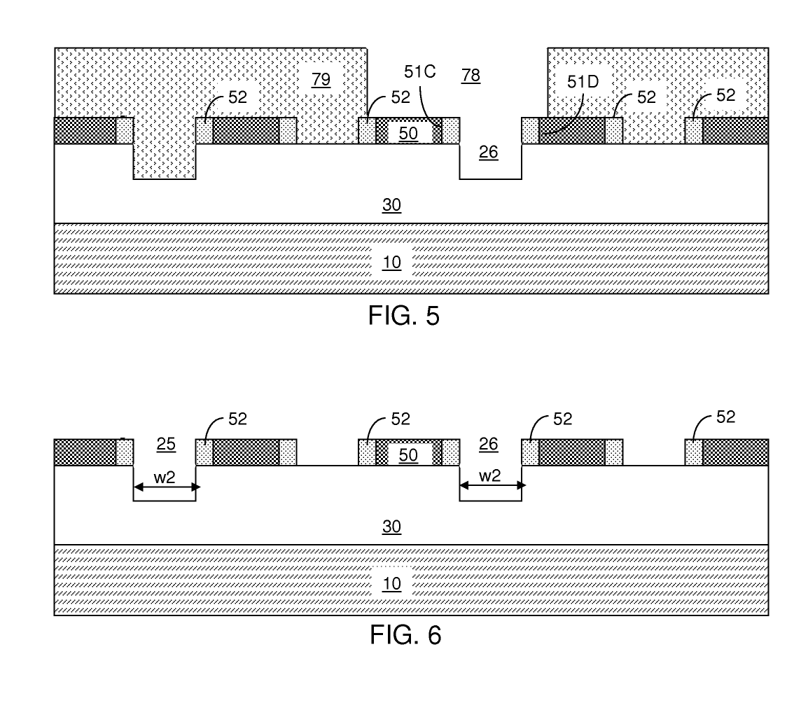

Referring to FIG. 5, an optional processing step for forming a second via cavity 26 is illustrated. In other words, formation of the second via cavity 26 may, or may not, be performed depending on embodiments. In an embodiment in which a second via cavity 26 is formed, a second via level photoresist layer 79 is applied over the patterned hard mask layer 50, the dielectric material layer 30, and the hard mask level spacers 52, for example, by spin coating. The second via level photoresist layer 79 is lithographically patterned with a via pattern including a second via opening 78. The via pattern in the lithographically patterned second via level photoresist layer 79 is herein referred to as a second via pattern. The second via opening 78 overlies a line opening having the second width w2 (e.g., the second from the right line opening), and can overlie all or a portion of the hard mask level spacer 52 that laterally surrounds the line opening. Further, the second via opening 78 can overlie any portion of the hard mask layer 50 around the line opening and the hard mask level spacer 52. In addition, the second via opening 78 can overlie any other hard mask level spacer 52, provided that the second via opening 78 does not overlie another line opening at which formation of a via is not desired. The second via pattern can include any additional second via opening(s) (not expressly shown) as needed.

The presence of the hard mask level spacer 52 extends the overlay window for printing the second via opening 78 along the direction of the second width w2 through the same mechanism through which the presence of the hard mask level spacer 52 extends the overlay window for printing the first via opening 76 along the direction of the second width w2.

Subsequently, an etch is performed to form at least one via cavity in a portion of the dielectric material layer 30. The etch is herein referred to as a second via etch, and employs the second via level photoresist layer 79, the hard mask layer 50, and the hard mask level spacers 52 as etch masks. The second via etch can be an anisotropic etch such as a reactive ion etch. The at least one via cavity is formed within an area corresponding to a composite pattern of an intersection of the second via pattern and the openings defined by inner sidewalls of the hard mask level spacers 52. Because the second via pattern includes the second via opening 78, the at least one via cavity can include a second via cavity 26 that is formed in an area corresponding to an intersection of the second via opening 78 and a line opening defined by the inner sidewalls of a hard mask level spacer 52, e.g., the hard mask level spacer 52 located in the second from the right opening in the hard mask layer 50 in FIG. 5.

The second via cavity 26 includes two parallel sidewalls that are laterally spaced by the second width w2. One of the two parallel sidewalls of the second via cavity 26 is laterally offset from a third sidewall 51C of the hard mask layer 50 (i.e., the left side sidewall around the second from the right opening in the hard mask layer 50) by an offset distance that is the same as the spacer width sw, and another of the two parallel sidewalls of the hard mask layer 50 is laterally offset from a fourth sidewall 51D of the hard mask layer 50 (i.e., the right side sidewall around the second from the right opening in the hard mask layer 50) by the same offset distance, i.e., the spacer width sw.

A pair of sidewalls (not shown) of the second via cavity 26 that laterally adjoins the two parallel sidewalls of the second via cavity 26 replicates two peripheral portions of a horizontal cross-sectional shape of the second via opening 78 that overlies the line opening (i.e., the second from the right line opening having the second width w2). In this case, the pair of sidewalls of the second via cavity 26 can be a pair of curvilinear sidewalls. Thus, the pair of sidewalls of the second via cavity 26 can be straight or curved.

Referring to FIG. 6, the second via level photoresist layer 79, if employed, is removed, for example, by ashing.

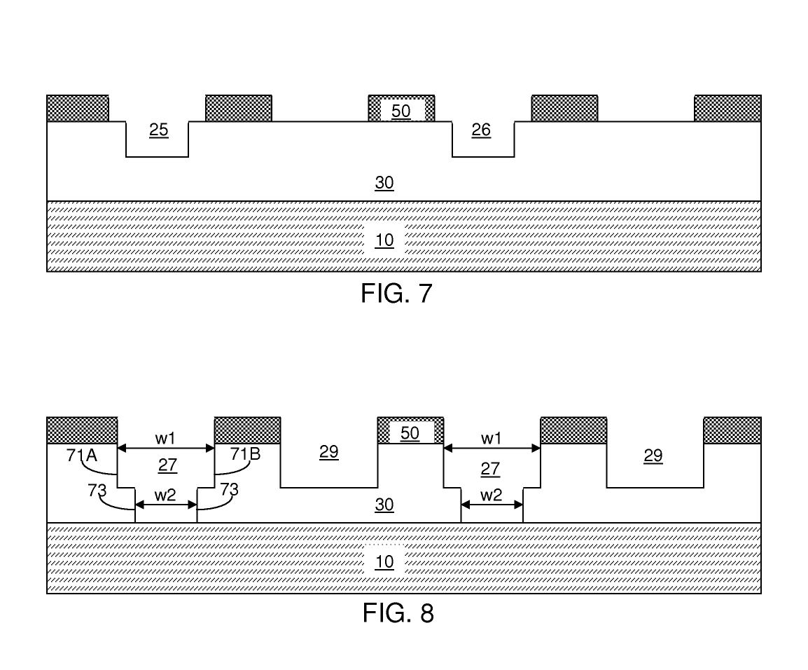

Referring to FIG. 7, the hard mask level spacers 52 are removed selective to the dielectric material layer 30. In one embodiment, the hard mask level spacers 52 can be removed selective to the dielectric material layer 30 and the hard mask layer 50. The removal of the hard mask level spacers 52 can be performed by a wet etch or a dry etch having an etch chemistry that is selective to the material of the dielectric material layer 30 and the material of the hard mask layer 50.

If the hard mask level spacers 52 include germanium, a silicon germanium alloy, or an oxide of a silicon germanium alloy, the material of the hard mask level spacers 52 can be removed by an etch that include hydrogen peroxide, which converts germanium into germanium oxide and dissolves the material of the hard mask level spacers 52 in a solution of hydrogen peroxide. The material(s) of the dielectric material layer 30 can be selected among materials that are not etched by hydrogen peroxide, and can include silicon oxide, silicon nitride, silicon oxynitride, an organosilicate glass, or combinations thereof. The material of the hard mask layer 50 can be selected from a metal, an intermetallic alloy, a metallic nitride, a metallic carbide, a metal oxide, and a dielectric material that is not etched by hydrogen peroxide. Alternately, the material of the hard mask level spacers 52 can be converted to a material that includes germanium oxide by an oxidation process, which can employ oxygen or ozone. The oxidation process can be a thermal oxidation process or a plasma assisted oxidation process. The germanium containing material can be subsequently removed, for example, by a wet etch employing hydrogen peroxide or water.

If the hard mask level spacers 52 include parylene or amorphous carbon, the material of the hard mask level spacers 52 can be volatilized and removed by an etch that converts the material of the hard mask level spacers 52 into a volatile compound such as CO₂. Further, a nitrogen plasma or a hydrogen plasma can be employed to convert the material of the hard mask level spacers 52 into a volatile compound. The material(s) of the dielectric material layer 30 can be selected among materials that are not converted into a volatile compound, and can include silicon oxide, silicon nitride, silicon oxynitride, an organosilicate glass, or combinations thereof. The material of the hard mask layer 50 can be selected from a metal, an intermetallic alloy, a metallic nitride, a metallic carbide, a metal oxide, and a dielectric material that is not converted into a volatile compound by the conversion process that removes the material of the hard mask level spacers.

If the hard mask level spacers 52 include a hydrogen-containing silicon nitride material, the hydrogen-containing silicon nitride material can be removed by an etch employing an etchant that removes the hydrogen-containing silicon nitride material at a greater etch rate than the dielectric material(s) of the dielectric material layer 30, which can include silicon oxide, silicon nitride that is substantially free of hydrogen, an organosilicate glass, or combinations thereof. An exemplary etchant is dilute hydrofluoric acid. It is noted that the presence of hydrogen in the hydrogen-containing silicon nitride material enhances the etch rate of the hydrogen-containing silicon nitride material compared to a silicon nitride material that is substantially free of hydrogen. The material(s) of the dielectric material layer 30 can be selected among materials that are not etched faster than the hydrogen-containing silicon nitride material, and can include silicon oxide, silicon nitride, silicon oxynitride, or combinations thereof. The material of the hard mask layer 50 can be selected from a metal, an intermetallic alloy, a metallic nitride, a metallic carbide, a metal oxide, and a dielectric material that is not etched by the etchant.

Thus, the hard mask level spacers 52 are removed selective to the material of the hard mask layer 50 and the material of the dielectric material layer 30, thereby physically exposing a peripheral top surface of the dielectric material layer 30 around each of the first via cavity 25 and the second via cavity 26.

Referring to FIG. 8, a dual damascene etch is performed to vertically recess horizontal surfaces of the dielectric material layer 30 that is not covered by the hard mask layer 50. The dual damascene etch can be an anisotropic etch, such as a reactive ion etch, that employs the hard mask layer 50 as an etch mask.

Each of the first via cavity 25 and the second via cavity 26 is vertically recessed to form a via cavity portion of a dual damascene cavity 27. Each dual damascene cavity 27 includes a line cavity having the first width w1 in an upper portion thereof and a via cavity including two parallel sidewalls spaced by the second width w2 in a lower portion thereof. In addition, additional line cavities, i.e., stand-alone line cavities 29, are formed underneath each line opening of the hard mask layer 50 that does not include any via cavity underneath. Thus, the dual damascene cavities 27 and the stand-alone line cavities 29 are simultaneously formed within the dielectric material layer 30.

Each dual damascene cavity 27 can include a first sidewall 71A and a second sidewall 71B spaced by the first width w1, and the two parallel sidewalls 73 that are parallel to the first sidewall 71A and the second sidewall 71B. One of the two parallel sidewalls 73 can be laterally offset from the first sidewall 71A by an offset distance that is substantially the same as the spacer width sw (See FIG. 3), and another of the two parallel sidewalls 73 can be laterally offset from the second sidewall 71B by the same offset distance.

In one embodiment, the two parallel sidewalls 73 can adjoin a planar bottom surface of a line cavity within the dual damascene cavity 27. The line cavity within each dual damascene cavity 27 can extend further along the lengthwise direction of the line cavity, i.e., along a horizontal direction perpendicular to the first width w1, than the underlying via cavity within the same dual damascene cavity.

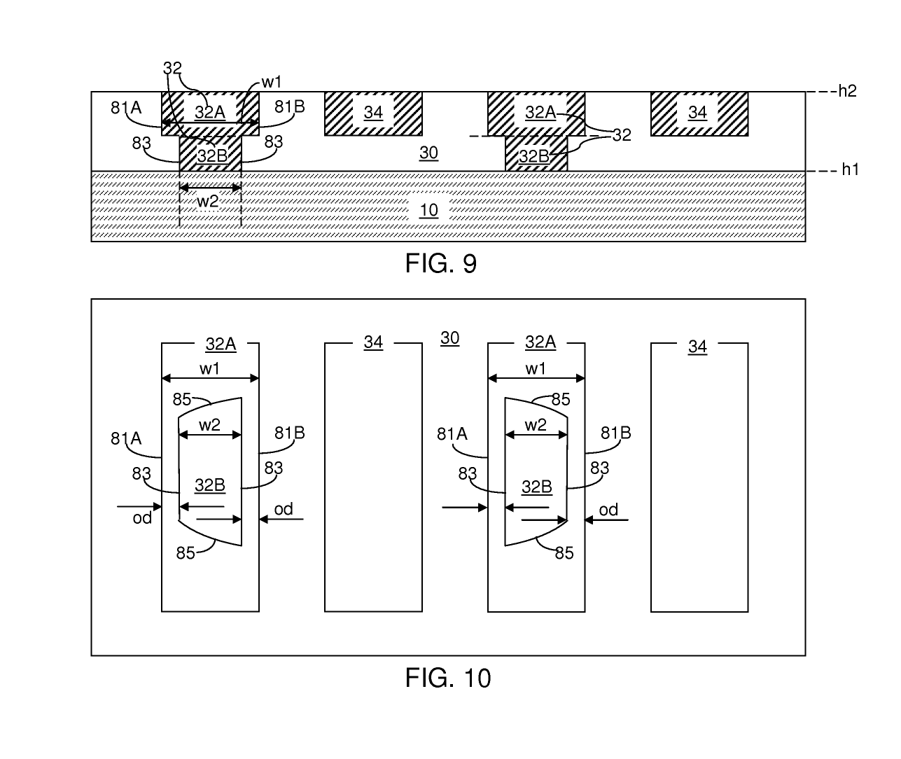

Referring to FIGS. 9 and 10, at least one conductive material is deposited within each of the dual damascene cavities 27 and the stand-alone line cavities 29 employing methods known in the art, which can include, for example, physical vapor deposition (PVD), chemical vapor deposition (CVD), electroplating, electroless plating, or combinations thereof. Non-limiting examples of at least one conductive material include Cu, Al, Au, Ag, W, Ti, Ta, WN, TiN, TaN, WC, TiC, WC, or combinations thereof. The at least one conductive material is subsequently planarized, for example, by chemical mechanical planarization (CMP) and/or a recess etch.

If the hard mask layer 50 includes a conductive material, the hard mask layer 50 is removed during the planarization process. In this case, the top surface of the dielectric material layer 30 can be employed as a stopping surface or an endpoint detection surface during the planarization process. If the hard mask layer 50 includes a dielectric material, the hard mask layer 50 may, or may not, be removed during the planarization process. In this case, the top surface of the hard mask layer 50 or the top surface of the dielectric material layer 30 can be employed as a stopping surface or an endpoint detection surface during the planarization process.

A dual damascene line-via structure 32 including the at least one conductive material is formed within each dual damascene cavity 27. A stand-alone line structure 34 including the at least one conductive material is formed within each stand-alone line cavity 29. Each dual damascene line-via structure 32 is an integrated line and via structure of integral construction that includes a metal line 32A having the first width w1 and a via structure 32B having two parallel sidewalls 83 spaced by the second width w2.

The metal line 32A includes a first sidewall 81A and a second sidewall 81B spaced by the first width w1. The two parallel sidewalls 83 are parallel to the first sidewall 81A of the metal line 32A and the second sidewall 81B of the metal line 32A. One of the two parallel sidewalls 83 is laterally offset from the first sidewall 81A of the metal line 32A by an offset distance od, and another of the two parallel sidewalls 83 is laterally offset from the second sidewall 81B of the metal line 32A by the offset distance od.

Each via structure 32B includes a pair of curvilinear sidewalls 85 laterally adjoining the two parallel sidewalls 83 and underlying the metal line 32A. In one embodiment, the pair of curvilinear sidewalls 85 can be a pair of curved sidewalls. Each via structure 32B can extend to the bottommost surface of the dielectric material layer 30.

Each stand-alone line structure 34 is a metal line structure embedded within the dielectric material layer 30, and has a bottommost surface that is coplanar with a bottommost portion of the metal line 32A within a dual damascene line-via structure 32.

Each metal line 32A within a dual damascene line-via structure 32 can extend further along a lengthwise direction of the metal line 32A that is perpendicular to the first width w1 than the underlying via structure 32B.

In one embodiment, the dielectric material layer 30 can have a homogenous composition within a height range extending at least from a first height h1 located below a horizontal plane of a topmost surface of the two parallel sidewalls 83 to a second height h2 located above the horizontal plane of a bottommost surface of a metal line 32A within a dual damascene line-via structure 32. The first height h1 can be any height below a horizontal plane of a topmost surface of the two parallel sidewalls 83 and at, or above, the bottommost surface of the dielectric material layer 30. The second height h2 can be any height above the horizontal plane of the bottommost surface of a metal line 32A within a dual damascene line-via structure 32 and at, or below, the topmost surface of the dielectric material layer 30.

In one embodiment, the two parallel sidewalls 83 can contact a planar bottom surface of the metal line 32A within a dual damascene line-via structure 32. In this case, the two parallel sidewalls 83 can adjoin the planar bottom surface of the metal line at right angle.

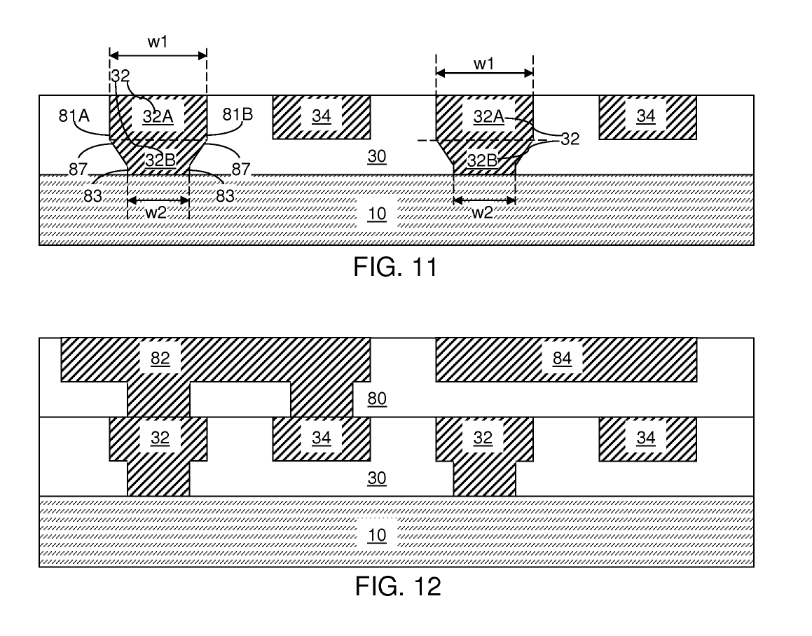

Referring to FIG. 11, a variation of the exemplary structure can be derived from the exemplary structure of FIG. 7 by performing a dual damascene etch employing a chemistry that generates tapered sidewalls from physically exposed portions of the topmost surface of the dielectric material layer 30 at the processing step of FIG. 8. In this case, an etch chemistry that generates polymers can be employed to form a combination of tapered sidewalls located at an upper portion of a via cavity and straight (vertical) sidewalls located at a lower portion of the via cavity. Thus, each via cavity located at a bottom portion of a dual damascene cavity 27 includes two tapered sidewalls that adjoin a bottom portion of a line cavity and top portions of the two parallel vertical sidewalls.

Subsequently, the processing steps of FIGS. 9 and 10 are performed. A dual damascene line-via structure 32 including the at least one conductive material is formed within each dual damascene cavity 27. A stand-alone line structure 34 including the at least one conductive material is formed within each stand-alone line cavity 29. Each dual damascene line-via structure 32 is an integrated line and via structure of integral construction that includes a metal line 32A having the first width w1 and a via structure 32B having two parallel sidewalls 83 spaced by the second width w2.

A dual damascene line-via structure 32 including the at least one conductive material is formed within each dual damascene cavity 27. A stand-alone line structure 34 including the at least one conductive material is formed within each stand-alone line cavity 29. Each dual damascene line-via structure 32 is an integrated line and via structure of integral construction that includes a metal line 32A having the first width w1 and a via structure 32B having two parallel sidewalls 83 spaced by the second width w2.

The metal line 32A includes a first sidewall 81A and a second sidewall 81B spaced by the first width w1. The two parallel sidewalls 83 are parallel to the first sidewall 81A of the metal line 32A and the second sidewall 81B of the metal line 32A. One of the two parallel sidewalls 83 is laterally offset from the first sidewall 81A of the metal line 32A by an offset distance od, and another of the two parallel sidewalls 83 is laterally offset from the second sidewall 81B of the metal line 32A by the offset distance od.

Each via structure 32B includes a pair of tapered sidewalls 87 adjoining the first and second sidewalls (81A, 81B) of the metal line 32 at an upper end thereof and adjoining the two parallel sidewalls 83 at a lower end thereof.

Referring to FIG. 12, an overlying dielectric material layer 80 and overlying metal interconnect structures (82, 84) can be optionally formed. The overlying metal interconnect structures (82, 84) can be formed employing the same methods as employed to form the metal interconnect structure including the dielectric material layer 30, the dual damascene line-via structures 32, and the stand-alone line structures 34, and can include at least one overlying dual damascene line-via structure 82 and at least one overlying stand-alone metal line 84.

While the disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the disclosure is intended to encompass all such alternatives, modifications and variations which fall within the scope and spirit of the disclosure and the following claims.

What is claimed is:

1. A method of forming a metal interconnect structure comprising:
forming a hard mask layer over a dielectric material layer;
patterning said hard mask layer with a line pattern including a line opening having a first width;
forming a hard mask level spacer on sidewalls of said line opening, wherein inner sidewalls of said hard mask level spacer define another line opening having a second width less than said first width;
applying a photoresist layer over said hard mask layer and lithographically patterning said photoresist layer with a via pattern that includes a via opening overlying said another line opening; and
transferring, employing an etch, a composite pattern including an intersection of said via opening and said another line opening into a portion of said dielectric material layer.

2. The method of claim 1, wherein said etch employs said photoresist layer, said hard mask layer, and said hard mask level spacer as etch masks.

3. The method of claim 1, further comprising removing said hard mask level spacer selective to said dielectric material layer.

4. The method of claim 3, further comprising etching said dielectric material layer employing said hard mask layer as an etch mask after said removal of said hard mask level spacer.

5. The method of claim 4, further comprising forming a dual damascene cavity including a line cavity having said first width and a via cavity including two parallel sidewalls spaced by said second width by said etching of said dielectric material layer.

6. The method of claim 5, wherein said two parallel sidewalls adjoin a planar bottom surface of said line cavity after formation of said dual damascene cavity.

7. The method of claim 5, wherein said via cavity further comprises two tapered sidewalls that adjoin a bottom portion of said line cavity and top portions of said two parallel sidewalls.

8. The method of claim 1, wherein said hard mask layer comprises a metal layer, an intermetallic alloy layer, a metallic nitride layer, a metallic carbide layer, a metal oxide layer, another dielectric material layer having a different composition than said dielectric material layer, or a combination thereof.

9. The method of claim 8, wherein said hard mask level spacer has a composition different from said hard mask layer and said dielectric material layer, and is selected from a hydrogen-containing silicon nitride material, germanium, a silicon germanium alloy, an oxide of a silicon germanium alloy, paralyine, and amorphous carbon.

10. The method of claim 1, wherein said hard mask level spacer is formed by:
depositing a contiguous material layer over said hard mask layer and within said line opening; and
anisotropically etching said contiguous material layer to remove horizontal portions of said contiguous material layer, wherein a remaining portion of said contiguous material layer constitutes said hard mask level spacer.

11. A metal interconnect structure comprising an integrated line and via structure of integral construction embedded in a dielectric material layer, said integrated line and via structure including a metal line having a first width and a via structure having two parallel sidewalls spaced by a second width that is less than said first width.

12. The metal interconnect structure of claim 11, wherein said metal line further comprises a first sidewall and a second sidewall spaced by said first width, and said two parallel sidewalls are parallel to said first sidewall of said metal line and said second sidewall of said metal line.

13. The method interconnect structure of claim 12, wherein one of said two parallel sidewalls is laterally offset from said first sidewall of said metal line by an offset distance, and another of said two parallel sidewalls is laterally offset from said second sidewall of said metal line by said offset distance.

14. The metal interconnect structure of claim 13, wherein said two parallel sidewalls contact a planar bottom surface of said metal line.

15. The metal interconnect structure of claim 13, wherein said via structure further comprises a pair of tapered sidewalls adjoining said first and second sidewalls of said metal line at an upper end thereof and adjoining said two parallel sidewalls at a lower end thereof.

16. The metal interconnect structure of claim 13, wherein said via structure further comprises a pair of curvilinear sidewalls laterally adjoining said two parallel sidewalls and underlying said metal line.

17. The metal interconnect structure of claim 16, wherein said pair of curvilinear sidewalls is a pair of curved sidewalls.

18. The metal interconnect structure of claim 11, further comprising a metal line structure embedded within said dielectric material layer and having a bottommost surface that is coplanar with a bottommost portion of said metal line.

19. The metal interconnect structure of claim 11, wherein said metal line extends further along a lengthwise direction of said metal line that is perpendicular to said first width than said via structure.

20. The metal interconnect structure of claim 11, wherein said dielectric material layer has a homogenous composition within a height range extending at least from a first height located below a horizontal plane of a topmost surface of said two parallel sidewalls to a second height located above a horizontal plane of a bottommost surface of said metal line.
